(19) United States
(12) Patent Application Publication
(10) Pub. No.: US 2024/0349509 A1
(43) Pub. Date: Oct. 17, 2024

(54) SEMICONDUCTOR DEVICE AND METHOD OF MANUFACTURING THE SAME

(71) Applicant: Renesas Electronics Corporation, Tokyo (JP)

(72) Inventor: Tadashi YAMAGUCHI, Tokyo (JP)

(21) Appl. No.: 18/595,236

(22) Filed: Mar. 4, 2024

(30) Foreign Application Priority Data
Apr. 13, 2023 (JP) 2023-065681

(51) Int. Cl. H10B 51/30; H01L 21/28; H01L 29/51

(52) U.S. Cl. CPC H10B 51/30; H01L 29/40111; H01L 29/516

(57) ABSTRACT

A performance of a semiconductor device is improved. A gate insulating film is formed on a semiconductor substrate. A gate electrode is formed on the gate insulating film. A ferroelectric film and a metal film are formed between the gate insulating film and the gate electrode. A thickness of the metal film is smaller than a thickness of the ferroelectric film. The metal film is amorphous.

### CROSS-REFERENCE TO RELATED APPLICATION

The disclosure of Japanese Patent Application No. 2023-065681 filed on Apr. 13, 2023, including the specification, drawings and abstract is incorporated herein by reference in its entirety.

### BACKGROUND

The present invention relates to a semiconductor device and a method of manufacturing the same, and particularly relates to a semiconductor device including a ferroelectric film and a method of manufacturing the same.

In recent years, ferroelectric memory cells each using a ferroelectric film have been developed as semiconductor storage elements each operating at a low voltage. The ferroelectric memory cell is a nonvolatile memory cell in which a writing state and an erasing state of information are changed by control for a direction of polarization of the ferroelectric film.

There is disclosed technique listed below.
[Patent Document 1] Japanese Unexamined Patent Application Publication No. 2021-22602

The Patent Document 1 discloses a ferroelectric memory cell including a ferroelectric film and a metal film formed on the ferroelectric film. The metal film is made of titanium nitride or others, and has a thickness that is equal to or larger than 10 nm. A crystalized ferroelectric film is formed by a thermal process in a state in which the metal film is in contact with an amorphous ferroelectric film. In this case, crystal orientation of the ferroelectric film can be uniformed by a stress generated from the metal film.

### SUMMARY

Thermodynamically, it is known that a large stress is necessary for forming a ferroelectric phase. A titanium nitride film, a tungsten film or others is used as a metal film formed on a ferroelectric film. Generally, such a metal film has a thickness of about 10 nm, and is crystallized. Relation between properties of the metal film and the stress has not been sufficiently specified so far.

A main object of the present application is to provide a metal film capable of applying a large stress onto a ferroelectric film to improve a performance of a ferroelectric memory cell and improve a performance a semiconductor device. Other objects and novel characteristics will be apparent from the description of the present specification and the accompanying drawings.

The outline of the typical aspects of the embodiments disclosed in the present application will be briefly described as follows.

A semiconductor device according to an embodiment includes: a gate insulating film formed on a semiconductor substrate; a gate electrode formed on the gate insulating film; and a ferroelectric film and a first metal film formed between the gate insulating film and the gate electrode. A thickness of the first metal film is smaller than a thickness of the ferroelectric film, and the first metal film is amorphous.

A method of manufacturing a semiconductor device according to an embodiment includes: a step (a) of forming a gate insulating film; a step (b) of forming a first amorphous film on the gate insulating film; a step (c) of forming a first metal film on the gate insulating film; a step (d) of, after the step (b) and the step (c), crystallizing the first amorphous film to form an orthorhombic ferroelectric film by executing a thermal process in a state in which the first metal film is in contact with the first amorphous film; and a step (e) of, after the step (d), forming an electric conductive film for gate electrode on the ferroelectric film and the first metal film. A thickness of the first metal film is smaller than a thickness of the ferroelectric film, and the first metal film in the step (d) is amorphous.

According to an embodiment, a performance of a semiconductor device can be improved.

### BRIEF DESCRIPTIONS OF THE DRAWINGS

FIG. 1 is a cross-sectional view of a semiconductor device according to a first embodiment.

FIG. 2 is a table showing an example of a condition of voltage application to each portion of a memory cell at time of “writing”, “erasing” and “reading”.

FIG. 3 is a graph resulted from experiments made by the inventors of the present application.

FIG. 4 is a graph resulted from experiments made by the inventors of the present application.

FIG. 5 is a graph resulted from experiments made by the inventors of the present application.

FIG. 6 is a cross-sectional view showing a step of manufacturing a semiconductor device according to the first embodiment.

FIG. 7 is a cross-sectional view showing a step of manufacturing the semiconductor device, continued from FIG. 6.

FIG. 8 is a cross-sectional view showing a step of manufacturing the semiconductor device, continued from FIG. 7.

FIG. 9 is a cross-sectional view showing a step of manufacturing the semiconductor device, continued from FIG. 8.

FIG. 10 is a cross-sectional view showing a step of manufacturing the semiconductor device, continued from FIG. 9.

FIG. 11 is a cross-sectional view showing a step of manufacturing the semiconductor device, continued from FIG. 10.

FIG. 12 is a cross-sectional view showing a step of manufacturing the semiconductor device, continued from FIG. 11.

FIG. 13 is a cross-sectional view of a semiconductor device according to a first modification example.

FIG. 14 is a cross-sectional view of a semiconductor device according to a second modification example.

FIG. 15 is a cross-sectional view of a semiconductor device according to a third modification example.

### DETAILED DESCRIPTION

Hereinafter, embodiments will be described in detail with reference to the accompanying drawings. Note that components having the same function are denoted by the same reference signs throughout all the drawings for describing the embodiments, and the repetitive description thereof will be omitted. In addition, the description of the same or similar portions is not repeated in principle unless otherwise particularly required in the following embodiments.

### First Embodiment

### <Structure of Semiconductor Device>

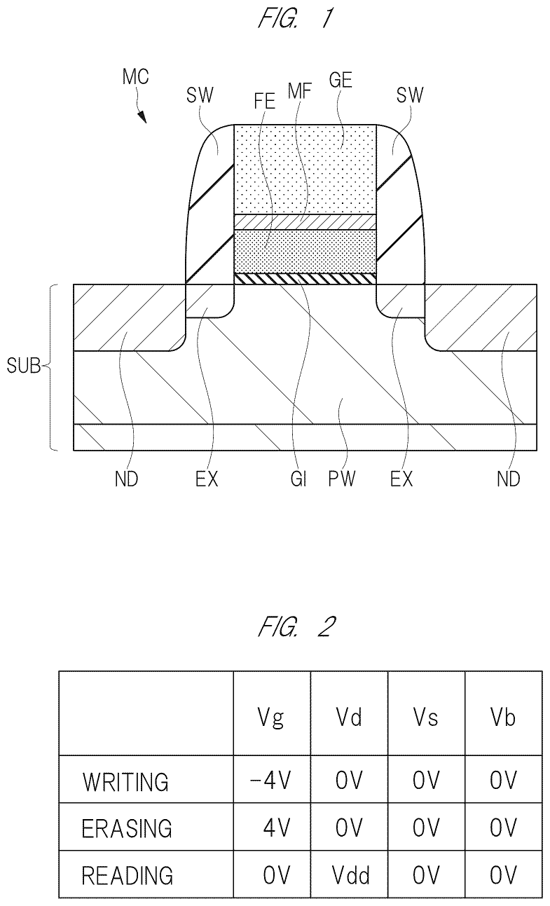

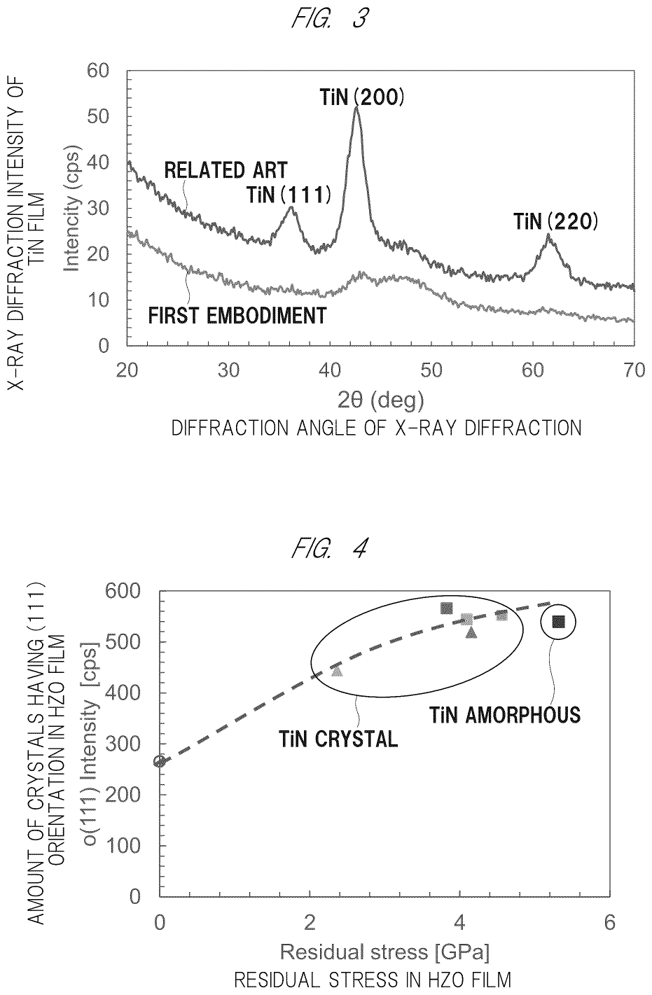

With reference to FIGS. 1 and 2, a semiconductor device according to a first embodiment will be explained below. The semiconductor device includes a memory cell MC. The memory cell MC is a nonvolatile memory cell, and is a ferroelectric memory cell.

As shown in FIG. 1, the memory cell MC includes a semiconductor substrate SUB, a gate insulating film GI, a ferroelectric film FE, a metal film MF, a gate electrode GE, a sidewall spacer SW, a well region PW, an extension region EX and a diffusion region ND.

The semiconductor substrate SUB is made of p-type single crystal silicon. A p-type well region PW is formed in the semiconductor substrate SUB. The gate insulating film (paraelectric film) GI is formed on the semiconductor substrate SUB including the well region PW. The gate insulating film GI is, for example, a silicon oxide film, and has a thickness that is, for example, equal to or larger than 0.1 nm and equal to or smaller than 3 nm.

The gate electrode GE is formed above the gate insulating film GI. The ferroelectric film FE and the metal film MF are formed between the gate insulating film GI and the gate electrode GE. In the first embodiment, the ferroelectric film FE is formed on the gate insulating film GI, the metal film MF is formed on the ferroelectric film FE, and the gate electrode GE is formed on the metal film MF. The gate electrode GE is, for example, a polycrystal silicon film doped with an n-type impurity.

The ferroelectric film FE is an insulating film made of a material causing dielectric polarization when electric field is externally generated and being polarized not to be zero even after removal of the electric field. In other words, the ferroelectric film FE is an insulating film made of a ferroelectric substance. Even in a state without the voltage application, the ferroelectric film FE includes a residual polarization having a certain amount.

And, the ferroelectric film FE needs to be an orthorhombic crystal. In other words, a film mainly made of a crystal other than the orthorhombic crystal is a paraelectric film. Therefore, the crystal configuring the ferroelectric film FE needs to be made of the orthorhombic crystal system as much as possible in order to increase the residual stress of the ferroelectric film FE, improve the performance as the ferroelectric substance, and reduce a driving power. The ferroelectric film FE in the first embodiment contains hafnium (Hf), oxygen (O) and zirconium (Zr). More specifically, the ferroelectric film FE is an orthorhombic HfZrO₂ film. A thickness of the ferroelectric film FE is, for example, equal to or larger than 4 nm and equal to or smaller than 10 nm. In the following explanation, note that the HfZrO₂ film is referred to as HZO film.

The metal film MF is a cap film formed to apply a stress to the ferroelectric film FE to control the crystal orientation of the ferroelectric film FE. The metal film MF in the first embodiment also functions as a part of the gate electrode GE. The metal film MF is amorphous, and is, for example, an amorphous titanium nitride film. A thickness of the metal film MF is smaller than a thickness of the ferroelectric film FE, and is, for example, equal to or larger than 1 nm and equal to or smaller than 4 nm, more preferably equal to or smaller than 2 nm.

A main feature of the first embodiment is that the metal film MF is an amorphous thin film. This feature will be explained in detail later.

The sidewall spacer SW is formed on a side surface of the gate electrode GE. The sidewall spacer SW is made of, for example, a stacked film of a silicon oxide film and a silicon nitride film.

The extension region EX that is a low-concentration n-type impurity region is formed in the well region PW below the sidewall spacer SW. The diffusion region ND that is a higher-concentration n-type impurity region than that of the extension region EX is formed in a part of the well region PW, the part being positioned to match the sidewall spacer SW. The extension region EX and the diffusion region ND are connected to each other, and are a part of a source region or a part of a drain region of the memory cell MC. A part of the well region PW, the part being immediately below the gate electrode GE and being sandwiched by two extension regions EX, becomes a channel region of the memory cell MC.

### <Operation of Memory Cell MC>

An operation example of the memory cell MC will be explained with reference to FIG. 2. A voltage Vg shown in FIG. 2 is a voltage applied to the gate electrode GE. A voltage Vd is a voltage applied to the drain region (either one of the diffusion regions ND). A voltage Vs is a voltage applied to the source region (the other of the diffusion regions ND). A voltage Vb is a voltage applied to the well region PW. Note that a magnitude of each voltage is not limited to that of FIG. 2, and is variously changeable if needed.

In the writing operation, by applying a voltage as shown in the “Writing” in FIG. 2, the polarization of the ferroelectric film FE is directed upward, and a threshold voltage of the memory cell MC is made relatively high. In the erasing operation, by applying a voltage as shown in the “Erasing” in FIG. 2, the polarization of the ferroelectric film FE is directed downward, and the threshold voltage of the memory cell MC is made relatively low.

In the reading operation, a voltage as shown in the “Reading” in FIG. 2 is applied. A voltage applied to the gate electrode GE at the time of the reading operation is set to be smaller than the threshold voltage of the memory cell MC in the writing state and to be larger than the threshold voltage of the memory cell MC in the erasing state. In the memory cell MC in the writing state, electric current does not flow, or an amount of the flow is small even if the electric current flows. In the memory cell MC in the erasing state, a large amount of the electric current flows. In this manner, a state of the memory cell MC can be determined based on the amount of the electric current flowing in the memory cell MC.

### <Feature of Metal Film MF>

With reference to FIGS. 3 to 5, the metal film MF in the first embodiment will be explained below.

The inventors of the present application have paid attention to the stress of the metal film MF, and have studied influence of this stress on the crystalline nature of the ferroelectric film FE in detail. A titanium nitride film (TiN film) was used as the metal film MF, and a HZO film was used as the ferroelectric film FE. After formation of the TiN film, a thermal process for crystallizing the ferroelectric film FE was executed. For the first time, it has been found out that the larger a change of the stress (residual stress) on the HZO film between before and after this thermal process is, the more the improvement of the crystalline nature of the HZO film is. The largest stress change was observed in an amorphous TiN film formed at an extremely low rate, and a thickness of this film was equal to or smaller than 2 nm.

FIG. 3 is a graph showing relation between a diffraction angle in an X-ray diffraction and an X-ray diffraction intensity of the TiN film. As shown in FIG. 3, the TiN film in the first embodiment does not have the crystal orientation. The TiN film is formed as a TiN film having weak orientation (crystalline nature) under a predetermined condition as the film forming condition. The weak orientation described herein means that, for example, a significant peak does not appear in the X-ray diffraction, and is in a state of the less ordered periodicity and symmetricity of fine crystals forming the film. Also, the weak orientation includes a state of disorder arrangement of the fine crystals forming the film, that is called “non-orientation” state.

A method of manufacturing such a TiN film will be explained. The TiN film is formed by a film forming process using a sputtering method. This film forming process is executed under conditions using a target made of titanium, a power for plasma formation to be equal to or lower than 1000 W, a pressure to be equal to or lower than 0.025 Pa, a flow rate of nitrogen to be equal to or lower than 12 sccm and a flow rate of argon to be equal to or lower than 15 sccm. The film is formed while plasma is discharged at a low power that is equal to or lower than 1000 W to chemically react the titanium and the nitrogen. A film forming rate of the TiN film in this film forming process is equal to or higher than 0.01 nm/sec and equal to or lower than 0.05 nm/sec, and is, for example, 0.02 nm/sec.

As shown in FIG. 3, such a film forming process can suppress formations of a TiN (111) plane, a TiN (200) plane and a TiN (220) plane that are preferred orientation planes. Generally, in a certain thickness, these crystal planes are naturally formed. However, the TiN film in the first embodiment has a thickness of about 2 nm, and therefore, is amorphous.

The amorphous HZO film is formed, and the TiN film is formed thereon, and then, the thermal process using, for example, a Rapid Thermal Annealing (RTA) method is executed. A temperature of this thermal process is, for example, equal to or higher than 500 degrees Celsius and equal to or lower than 600 degrees Celsius. By this thermal process, a large stress is applied on the TiN film. Then, the stress on the TiN film propagates to the HZO film, and phase transition (structural phase transition) of the amorphous HSZO film is caused to form an orthorhombic HZO film having high orientation (crystalline nature).

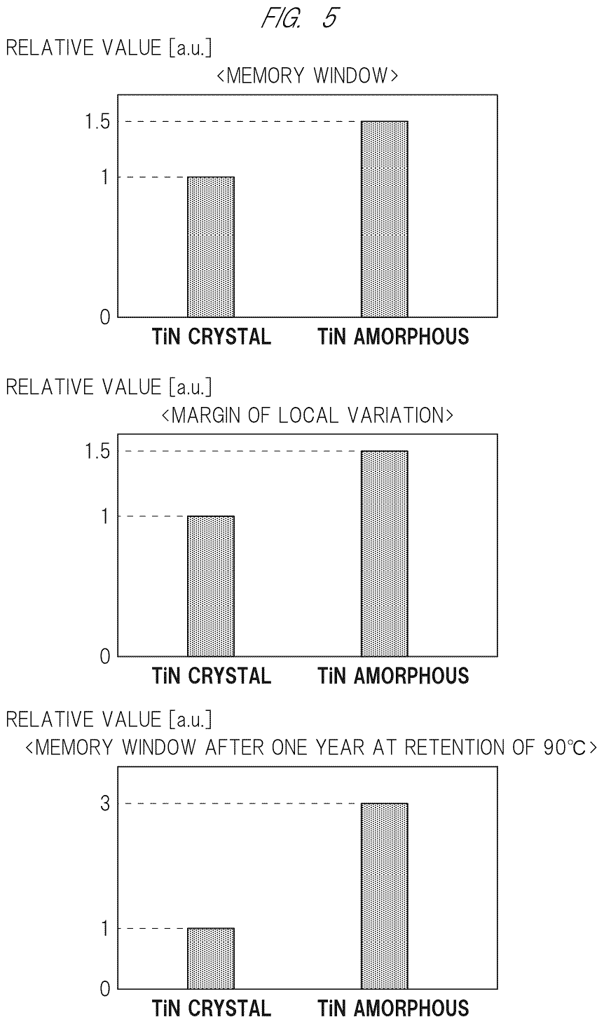

FIG. 4 is a graph showing a relation between the residual stress in the HZO film and an amount of crystals having (111) orientation in the HZO film. Note that a measurement point of the “TiN amorphous” in FIG. 4 is measured using the metal film MF of the first embodiment. And, each of a plurality of measurement points included in the “TiN crystal” in FIG. 4 has a different thickness, and is measured using the crystalized TiN film.

As shown in FIG. 4, the larger residual stress is formed in the use of the amorphous TiN film than the use of the crystalized TiN film. A reason why the large stress is formed on the TiN film in the first embodiment is possibly that the stress is increased by the thermal process since the TiN film having the weak orientation has a large linear coefficient of expansion.

FIG. 5 is a graph showing a measurement result of each property necessary for the memory cell MC, measured by the present inventors. Local variation and retention in a memory window and a wafer surface were measured. As shown in FIG. 5, improvement of each property was observed because of improvement of the crystalline nature of the HZO film. By the improvement of the crystalline nature of the HZO film, a writing speed and an erasing speed at a low voltage can be increased, and therefore, low voltage driving and low power consumption of the memory cell MC can be achieved.

As described above, the first embodiment can provide the metal film MF capable of applying the large stress onto the ferroelectric film FE. By the use of this metal film MF, the performance of the memory cell MC can be improved, and the performance of the semiconductor device can be improved.

### <Method of Manufacturing Semiconductor Device>

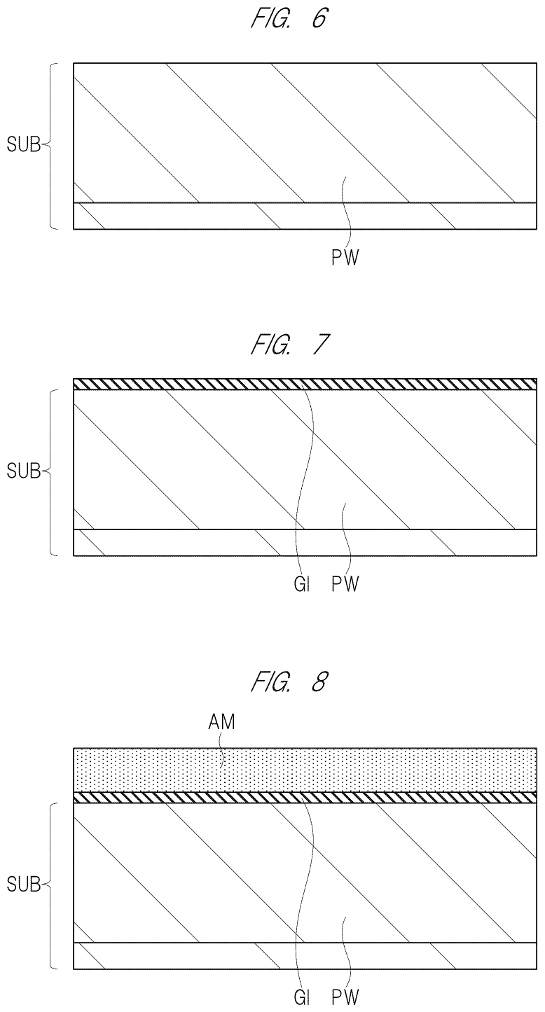

With reference to FIGS. 6 to 12, each manufacturing step included in a method of manufacturing the semiconductor device in the first embodiment will be explained below.

As shown in FIG. 6, first, the semiconductor substrate SUB made of, for example, a p-type single crystal silicon is prepared. Next, by a photolithography technique and an ion implantation method, the p-type well region PW is selectively formed in the semiconductor substrate SUB.

As shown in FIG. 7, the gate insulating film GI is formed on the semiconductor substrate SUB by, for example, a thermal oxidation process.

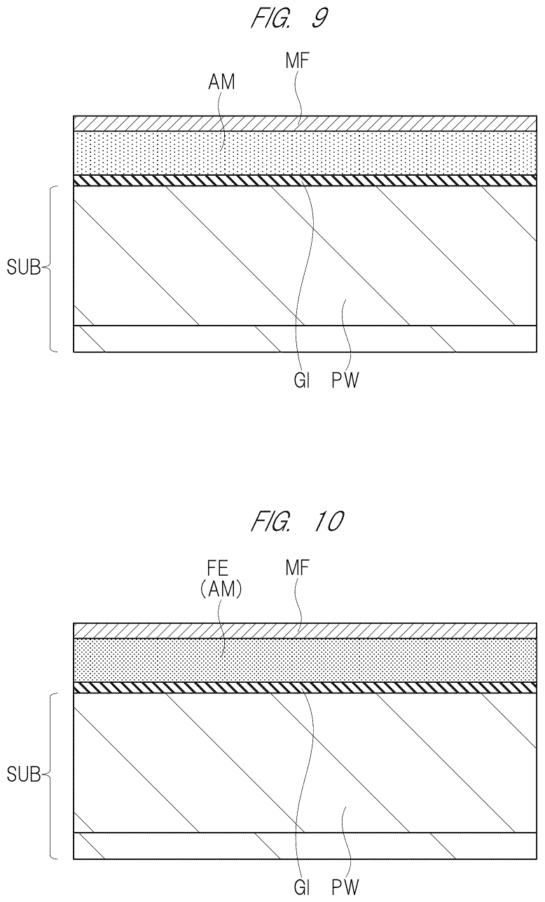

As shown in FIG. 8, an amorphous film AM is formed on the gate insulating film GI by, for example, an Atomic Layer Deposition (ALD) method. A thickness of the amorphous film AM is, for example, equal to or larger than 4 nm and equal to or smaller than 10 nm. The amorphous film AM contains hafnium (Hf), oxygen (O) and zirconium (Zr). More specifically, the amorphous film AM is a HfZrO₂ film (HZO film).

As shown in FIG. 9, the amorphous metal film MF is formed on the gate insulating film GI by a film forming process using, for example, a sputtering method. The metal film MF is, for example, an amorphous titanium nitride film (TiN film). A thickness of the metal film MF is smaller than the thickness of the amorphous film AM, and is, for example, equal to or larger than 1 nm and equal to or smaller than 4 nm, preferably equal to or smaller than 2 nm. Note that each condition of the film forming process of the metal film MF is the same as each condition explained in FIG. 3.

As described later in another embodiment, the metal film MF may be formed on the gate insulating film GI before the formation of the amorphous film AM. However, in the first embodiment, the metal film MF is formed on the gate insulating film GI after the formation of the amorphous film AM. Therefore, in the first embodiment, the metal film MF is formed on the amorphous film AM so that the metal film MF is in contact with the amorphous film AM.

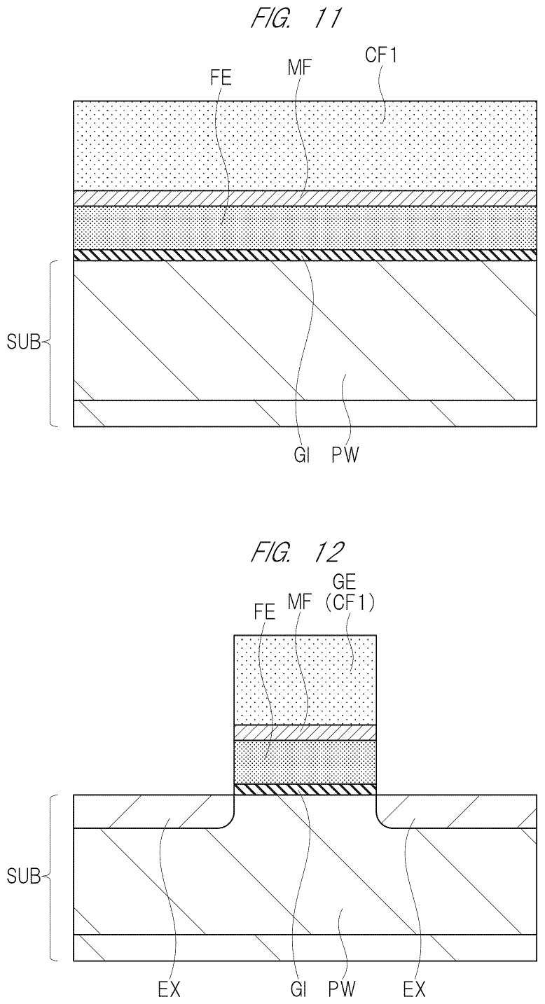

As shown in FIG. 10, when the thermal process is executed in the state in which the metal film MF is in contact with the amorphous film AM, the amorphous film AM is crystallized to form the orthorhombic ferroelectric film FE. This thermal process is called Rapid Thermal Annealing (RTA), and is executed under conditions of, for example, time that is equal to or longer than 1 second and equal to or shorter than 3 minutes and a temperature that is equal to or higher than 500 degrees Celsius and equal to or lower than 600 degrees Celsius. Note that the amorphous state of the metal film MF is maintained even after this thermal process.

By this thermal process, the large stress is applied on the metal film MF. Then, the stress on the metal film MF propagates to the amorphous film AM, and phase transition of the amorphous film AM is caused to form the orthorhombic ferroelectric film FE having high orientation. In this case, as described in FIG. 4, the change of the stress applied on the ferroelectric film FE can be made larger in the amorphous metal film MF than the crystal metal film MF.

As shown in FIG. 11, after the thermal process of FIG. 10, the electric conductive film CF1 for the gate electrode GE is formed on the metal film MF by, for example, a Chemical Vapor Deposition (CVD) method. The electric conductive film CF1 is made of, for example, polycrystal silicon doped with an n-type impurity.

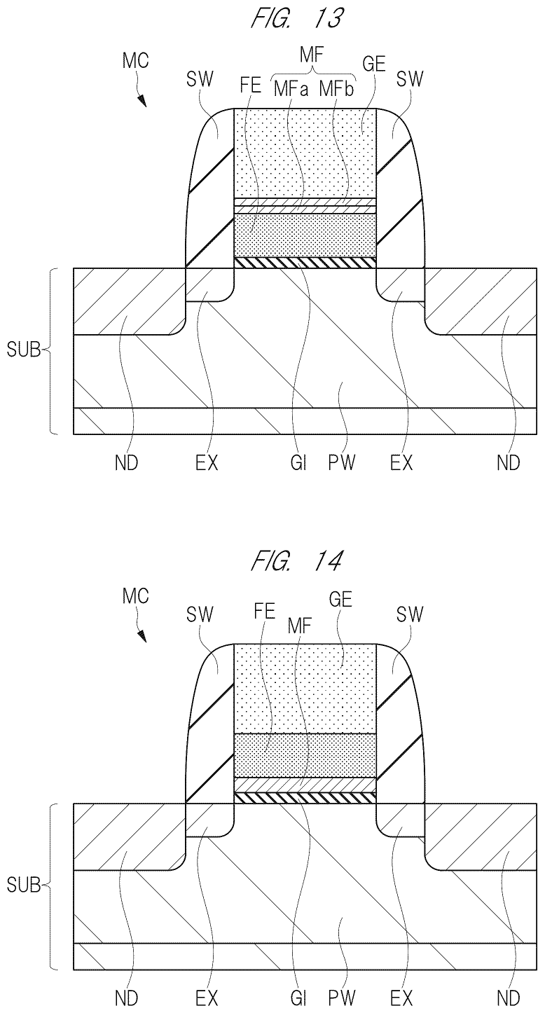

As shown in FIG. 12, first, by a photolithography technique and an anisotropic etching process, the electric conductive film CF1, the metal film MF, the ferroelectric film FE and the gate insulating film GI are sequentially patterned. The patterned electric conductive film CF1 becomes the gate electrode GE.

Next, by a photolithography technique and an ion implantation method, the extension region EX that is an n-type impurity region is formed inside the well region PW exposed from the gate electrode GE.

Then, through the following manufacturing steps, the memory cell MC shown in FIG. 1 is formed.

First, a stacked film of, for example, a silicon oxide film and a silicon nitride film is formed so as to cover the gate electrode GE by, for example, a CVD method. Next, by an anisotropic etching process, the stacked film is processed to form the sidewall spacer SW made of the stacked film on a side surface of the gate electrode GE.

Next, by a photolithography technique and an ion implantation method, the diffusion region ND that is an n-type impurity region is formed inside the well region PW exposed from the sidewall spacer SW and the gate electrode GE. The diffusion region ND has a higher impurity concentration than that of the extension region EX. Each of the diffusion region ND and the extension region EX functions as a part of the source region or a part of the drain region of the memory cell MC.

### First Modification Example

With reference to FIG. 13, a semiconductor device according to a first modification example of the first embodiment will be explained below. In the following explanation, note that differences from the first embodiment are mainly explained, and explanation for overlapping points with the first embodiment is omitted.

In the first embodiment, the metal film MF is the single amorphous film. In the first modification example, the metal film MF is a stacked film including a plurality of amorphous films.

As shown in FIG. 13, the metal film MF according to the first modification example includes an amorphous film MFa and an amorphous film MFb. Each of the amorphous film MFa and the amorphous film MFb is formed by a film forming process under the same conditions as those explained in FIG. 3 as similar to the first embodiment. Each of the amorphous film MFa and the amorphous film MFb is, for example, an amorphous titanium nitride film. A thickness of each of the amorphous film MFa and the amorphous film MFb is smaller than the thickness of the ferroelectric film FE, and is, for example, equal to or larger than 1 nm and equal to or smaller than 4 nm, preferably equal to or smaller than 2 nm.

When the amorphous film MFa and the amorphous film MFb are sequentially stacked in FIG. 9 by a film forming process under the same conditions as those explained in FIG. 3, the metal film MF according to the first modification example can be formed. Even in the first modification example, since the entire metal film MF is amorphous, the change of the stress applied on the ferroelectric film FE can be increased.

In the first modification example, by the stacking of the plurality of amorphous films such as the amorphous film MFa and the amorphous film MFb, a work function of the entire metal film MF can be finely adjusted. Therefore, by adjustment of each thickness of the plurality of amorphous films and the number of the stacks of the plurality of amorphous films, the threshold voltage of the memory cell MC can be finely adjusted.

In the first modification example, note that the metal film MF is exemplified to have the two-layered structure made of the amorphous film MFa and the amorphous film MFb. However, the metal film MF may be two- or more-layered amorphous films.

The metal film MF having the stacked structure according to the first modification example is also applicable to all metal films MF disclosed in second and third modification examples described later.

### Second Modification Example

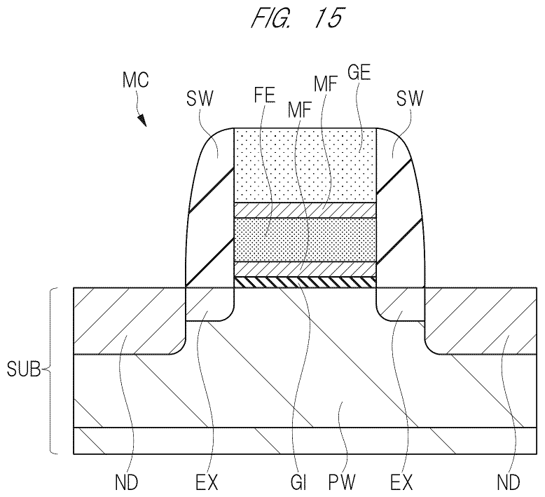

With reference to FIG. 14, a semiconductor device according to a second modification example will be explained below. In the following explanation, note that differences from the first embodiment are mainly explained, and explanation for overlapping points with the first embodiment is omitted.

In the first embodiment, the metal film MF is formed between the ferroelectric film FE and the gate electrode GE. As shown in FIG. 14, the metal film MF in the second modification example is formed between the ferroelectric film FE and the gate insulating film GI.

In order to provide such a structure of the second modification example, the metal film MF may be formed on the gate insulating film GI first, and then, the amorphous film AM may be formed on the metal film MF. Note that the metal film MF in the second modification example can be formed by a film forming process under the same conditions as those explained in FIG. 3.

Even in the second modification example, when the thermal process of FIG. 10 is executed in the state in which the metal film MF is in contact with the amorphous film AM, the change of the stress applied on the ferroelectric film FE can be increased, and the orthorhombic ferroelectric film FE can be formed. In the second modification example, note that the electric conductive film CF1 for the gate electrode GE is formed on the ferroelectric film FE.

### Third Modification Example

With reference to FIG. 15, a semiconductor device according to a third modification example will be explained below. In the following explanation, note that differences from the first embodiment are mainly explained, and explanation for overlapping points with the first embodiment is omitted.

As shown in FIG. 15, in the third modification example, the metal film MF as similar to that of the first embodiment is formed between the ferroelectric film FE and the gate electrode GE, and the metal film MF as similar to that of the second modification example is formed between the gate insulating film GI and the ferroelectric film FE.

In order to provide such a structure of the third modification example, the metal film MF is formed on the gate insulating film GI first. Then, the amorphous film AM is formed on the metal film MF. Then, the metal film MF is formed on the amorphous film AM. Note that the two metal films MF in the third modification example can be formed by a film forming process under the same conditions as those explained in FIG. 3.

Even in the third modification example, when the thermal process of FIG. 10 is executed in the state in which the two metal films MF are in contact with the amorphous film AM, the change of the stress applied on the ferroelectric film FE can be increased, and the orthorhombic ferroelectric film FE can be formed. Since the thermal process is executed in the state in which up and down sides of the amorphous film AM are sandwiched by the two metal films MF, the larger change of the stress than that of the first embodiment or the second modification example can be generated.

In the foregoing, the present invention has been concretely described on the basis of the embodiments. However, the present invention is not limited to the foregoing embodiments, and various modifications can be made within the scope of the present invention.

What is claimed is:

1. A semiconductor device comprising:
a gate insulating film formed on a semiconductor substrate;
a gate electrode formed on the gate insulating film; and
a ferroelectric film and a first metal film formed between the gate insulating film and the gate electrode,
wherein a thickness of the first metal film is smaller than a thickness of the ferroelectric film, and
wherein the first metal film is amorphous.

2. The semiconductor device according to claim 1,
wherein the thickness of the first metal film is equal to or larger than 1 nm and equal to or smaller than 4 nm.

3. The semiconductor device according to claim 2,
wherein the thickness of the first metal film is equal to or smaller than 2 nm.

4. The semiconductor device according to claim 2,
wherein the first metal film is made of amorphous titanium nitride.

5. The semiconductor device according to claim 4,
wherein the ferroelectric film contains hafnium, oxygen and zirconium.

6. The semiconductor device according to claim 1,
wherein the first metal film is a stacked film including a plurality of amorphous films, and
wherein each thickness of the plurality of amorphous films is equal to or smaller than 2 nm.

7. The semiconductor device according to claim 1,
wherein the first metal film is formed between the ferroelectric film and the gate electrode.

8. The semiconductor device according to claim 7 further comprising
a second metal film formed between the gate insulating film and the ferroelectric film,
wherein a thickness of the second metal film is smaller than the thickness of the ferroelectric film, and
wherein the second metal film is amorphous.

9. The semiconductor device according to claim 1,
wherein the first metal film is formed between the gate insulating film and the ferroelectric film.

10. A method of manufacturing a semiconductor device comprising steps of:
(a) forming a gate insulating film on a semiconductor substrate;
(b) forming a first amorphous film on the gate insulating film;
(c) forming a first metal film on the gate insulating film;
(d) after the step (b) and the step (c), crystallizing the first amorphous film to form an orthorhombic ferroelectric film by executing a thermal process in a state in which the first metal film is in contact with the first amorphous film; and
(e) after the step (d), forming an electric conductive film for gate electrode on the ferroelectric film and the first metal film,
wherein a thickness of the first metal film is smaller than a thickness of the first amorphous film, and
wherein, in the step (d), the first metal film is amorphous.

11. The method of manufacturing the semiconductor device according to claim 10,
wherein the thickness of the first metal film is equal to or larger than 1 nm and equal to or smaller than 4 nm.

12. The method of manufacturing the semiconductor device according to claim 11,
wherein the thickness of the first metal film is equal to or smaller than 2 nm.

13. The method of manufacturing the semiconductor device according to claim 11,
wherein, in the step (c), the first metal film is formed by a film forming process using a sputtering method, and
wherein a film forming rate of the first metal film in the film forming process is equal to or higher than 0.01 nm/sec and equal to or lower than 0.05 nm/sec.

14. The method of manufacturing the semiconductor device according to claim 13,
wherein the film forming process is executed under conditions using a target made of titanium, a power for plasma formation to be equal to or lower than 1000 W, a pressure to be equal to or lower than 0.025 Pa, a flow rate of nitrogen to be equal to or lower than 12 sccm and a flow rate of argon to be equal to or lower than 15 sccm.

15. The method of manufacturing the semiconductor device according to claim 14,
wherein the ferroelectric film contains hafnium, oxygen and zirconium.

16. The method of manufacturing the semiconductor device according to claim 10,
wherein, in the step (c), the first metal film is formed by sequentially stacking a plurality of amorphous films, and
wherein each thickness of the plurality of amorphous films is equal to or smaller than 2 nm.

17. The method of manufacturing the semiconductor device according to claim 10,
wherein the step (c) is executed after the step (b),
wherein, in the step (c), the first metal film is formed on the first amorphous film, and
wherein, in the step (e), the electric conductive film is formed on the first metal film.

18. The method of f manufacturing the semiconductor device according to claim 17 further comprising a step of,
(f) between the step (a) and the step (b), forming a second metal film on the gate insulating film,
wherein, in the step (b), the first amorphous film is formed on the second metal film,
wherein, in the step (d), the thermal process is executed in a state in which the first metal film and the second metal film are in contact with the first amorphous film,
wherein a thickness of the second metal film is smaller than the thickness of the first amorphous film, and
wherein, in the step (d), the second metal film is amorphous.

19. The method of manufacturing the semiconductor device according to claim 10,
wherein the step (c) is executed before the step (b),
wherein, in the step (b), the first amorphous film is formed on the first metal film, and
wherein, in the step (e), the electric conductive film is formed on the ferroelectric film.
